(19) United States
(12) Patent Application Publication
(10) Pub. No.: US 2026/0254425 A1
(43) Pub. Date: Aug. 27, 2026

(54) PHASE SHIFTER CIRCUIT ARCHITECTURES

(71) Applicant: Texas Instruments Incorporated, Dallas, TX (US)

(72) Inventors: Arnab Das, Bangalore (IN); Krishnanshu Dandu, Plano, TX (US)

(21) Appl. No.: 19/222,791

(22) Filed: May 29, 2025

(30) Foreign Application Priority Data
Feb. 21, 2025 (IN) 202541014884

(51) Int. Cl. H03F 3/24; H03M 1/70

(52) U.S. Cl. CPC H03F 3/245; H03M 1/70; H03F 2200/336

(57) ABSTRACT

An example apparatus includes first and second circuits to couple to a digital-to-analog converter. The apparatus includes (i) a first transistor including a first load terminal, a second load terminal coupled to a ground node, and a first control terminal coupled to the first circuit, (ii) a second transistor including a third load terminal, a fourth load terminal coupled to the ground node, and a second control terminal coupled to the first circuit, (iii) a third transistor including a fifth load terminal coupled to the third load terminal of the second transistor, a sixth load terminal coupled to the ground node, and a third control terminal coupled to the second circuit, and (iv) a fourth transistor including a seventh load terminal coupled to the first load terminal of the first transistor, an eighth load terminal coupled to the ground node, and a fourth control terminal coupled to the second circuit.

### CROSS-REFERENCE TO RELATED APPLICATIONS

This patent application claims the benefit of and priority to Indian Provisional Patent Application No. 202541014884 filed Feb. 21, 2025, which Application is hereby incorporated herein by reference in its entirety.

This patent application also incorporates by reference commonly assigned U.S. Pat. No. 9,602,054, titled “System and Method for Reconfigurable Phase Shifter and Mixer,” filed Nov. 2, 2015, commonly assigned U.S. Patent Application Publication No. 2023/0305132, titled “Phase Adjusting FMCW Radar System,” filed Sep. 20, 2022, and commonly assigned U.S. patent application Ser. No. 18/901,259, titled “Reflective Transmission Line with Negative Impedance Cells,” filed Sep. 30, 2024.

### TECHNICAL FIELD

This description relates generally to signal phase shifting and, more particularly, to phase shifter circuit architectures.

### BACKGROUND

Phase shifter circuits, also referred to as phase shifters, are employed in many systems, such as radar systems, communication systems, beamforming systems, etc. For example, a millimeter wave (mmWave) radar sensor product may include a multiple-input multiple-output (MIMO) transceiver having a number of transmitters that perform vector modulation with phase shifters. In at least some such examples, the phase shifter circuits support configurable phase shifts, such as over a range of 0 to 360 degrees, or some other range, which may be the same or different for different transmitters of the MIMO transceiver.

### SUMMARY

For methods and apparatus to implement phase shifter circuit architectures, an example device includes a first circuit configurable to be coupled to a digital-to-analog converter (DAC), a second circuit configurable to be coupled to the DAC, a first transistor, a second transistor, a third transistor and a fourth transistor. The first transistor includes a first load terminal, a second load terminal coupled to a ground node, and a first control terminal coupled to the first circuit. The second transistor includes a third load terminal, a fourth load terminal coupled to the ground node, and a second control terminal coupled to the first circuit. The third transistor includes a fifth load terminal coupled to the third load terminal of the second transistor, a sixth load terminal coupled to the ground node, and a third control terminal coupled to the second circuit. The fourth transistor includes a seventh load terminal coupled to the first load terminal of the first transistor, an eighth load terminal coupled to the ground node, and a fourth control terminal coupled to the second circuit.

For methods and apparatus to implement phase shifter circuit architectures, another example device includes a first circuit configurable to be coupled to a first digital-to-analog converter (DAC) output, the first DAC output configurable to provide a first current corresponding to an in-phase component of a phase shift. The example device includes a second circuit configurable to be coupled to a second DAC output, the second DAC output configurable to provide a second current corresponding to a quadrature component of the phase shift. The example device includes a first transistor having a first load terminal, a second load terminal and a control terminal, the control terminal of the first transistor coupled to the first circuit. The example device includes a second transistor having a first load terminal, a second load terminal and a control terminal, the control terminal of the second transistor coupled to the first circuit. The example device includes a third transistor having a first load terminal, a second load terminal and a control terminal, the control terminal of the third transistor coupled to the second circuit. The example device includes a fourth transistor having a first load terminal, a second load terminal and a control terminal, the control terminal of the fourth transistor coupled to the second circuit. In the example device, the first load terminals of the first transistor, the second transistor, the third transistor and the fourth transistor are cross-coupled to a circuit output, the circuit output to provide an output signal based on the phase shift.

For methods and apparatus to implement phase shifter circuit architectures, yet another example device includes an antenna, a power amplifier coupled to the antenna, a digital-to-analog converter (DAC) circuit having a first DAC output and a second DAC output, first circuitry coupled to the first DAC output and second circuitry coupled to the second DAC output. The example device includes a first transistor having a first load terminal, a second load terminal and a control terminal, the control terminal of the first transistor coupled to the first circuitry, the second load terminal of the first transistor coupled to a ground node. The example device includes a second transistor having a first load terminal, a second load terminal and a control terminal, the control terminal of the second transistor coupled to the first circuitry, the second load terminal of the second transistor coupled to the ground node. The example device includes a third transistor having a first load terminal, a second load terminal and a control terminal, the control terminal of the third transistor coupled to the second circuitry, the second load terminal of the third transistor coupled to the ground node. The example device includes a fourth transistor having a first load terminal, a second load terminal and a control terminal, the control terminal of the fourth transistor coupled to the second circuitry, the second load terminal of the fourth transistor coupled to the ground node. In the example device, the first load terminals of the first transistor and the third transistor are coupled to a first circuit output, the first load terminals of the second transistor and the fourth transistor are coupled to a second circuit output, and the first circuit output and the second circuit output are coupled to the power amplifier.

### BRIEF DESCRIPTION OF THE DRAWINGS

FIG. 1 is a block diagram of a first example system that includes example phase shifters that may be implemented using example phase shifter circuit architectures described herein.

FIG. 2 is a block diagram of a second example system that includes an example phase shifter that may be implemented using example phase shifter circuit architectures described herein.

FIG. 3 is a block diagram of a first example phase shifter circuit that may be used in the example systems of FIGS. 1 and/or 2.

FIG. 4 is a block diagram of a second example phase shifter circuit that may be used in the example systems of FIGS. 1 and/or 2.

FIGS. 5A-5C illustrate example intrinsic nonlinear characteristics associated with the second example phase shifter of FIG. 4.

FIG. 6 is a block diagram of a third example phase shifter circuit that may be used in the example systems of FIGS. 1 and/or 2.

FIGS. 7A-7B illustrates example performance results associated with the third example phase shifter of FIG. 6.

FIG. 8 is a flowchart representative of example machine-readable instructions or example operations that may be at least one of executed, instantiated, or performed to configure the third example phase shifter circuit of FIG. 6.

FIG. 9 is a block diagram of an example processing platform including programmable circuitry structured to execute, instantiate, or perform the example machine-readable instructions or perform the example operations of FIG. 8 to configure the phase shifter circuit of FIG. 6.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Phase shifter circuits, also referred to herein as phase shifters, are employed in various types of systems to apply phase shifts to signals. For example, radar systems and communications systems may employ phase shifters to phase modulate the signals transmitted and/or received by such systems. As another example, beamforming systems may employ phase shifters in combination with antenna arrays to transmit signals to and/or receive signals from a particular direction.

Phase integral non-linearity (INL) is a metric that can be used to characterize the accuracy of phase shifter circuits. Some phase shifters that support a range of phase shifts from 0 to 360 degrees can achieve INL of approximately 13-15 degrees, which means the error between the target phase shift provides as input to the phase shifter and the actual phase shift produced by the phase shifter can be approximately 13-15 degrees. Dividing the full range of phase shifts (e.g., 360 degrees) by the INL error (e.g., 13-15 degrees) yields an effective raw phase resolution of 5-bits for such phase shifters. In some implementations, calibration can be used to improve such phase shifters to achieve 6-bit resolution by decreasing the INL error.

However, even calibrated to achieve 6-bit resolution, such phase shifters still produce phase shifts with up to 5 degrees of error, which may be insufficient for some applications. For example, radar systems employed for autonomous driving applications, high-speed communications systems, etc., may require phase shifters that can achieve better than 6-bit resolution. Example phase shifter circuit architectures described herein are able to achieve raw phase resolutions of 6-bits or better, which can be calibrated to achieve calibrated resolutions of 7-bits or better. As such, phase shifter circuit architectures described herein can produce phase shifts with phase error reduced by 50% or more relative to the phase shifters described above.

Example phase shifter circuit architectures disclosed herein utilize one or more design innovations to achieve such performance improvement. Some example phase shifter circuit architectures described herein reposition the transistors that are used to receive the input signals that correspond to the configured (e.g., programmed) phase shift to allow such signals to have a higher dynamic range than is possible with the other phase shifters described above, which can improve the linearity of the configured phase shifts represented by those input signals. Such transistor positioning also eliminates other causes of circuit nonlinearity, as described in further detail below. Some example phase shifter architectures described herein also include programmable bleed current sources to bias the input signals corresponding to the configured (e.g., programmed) phase shift to have signal values outside a range in which the phase shifter circuit may exhibit substantial INL, thereby further improving INL performance relative to other phase shifters.

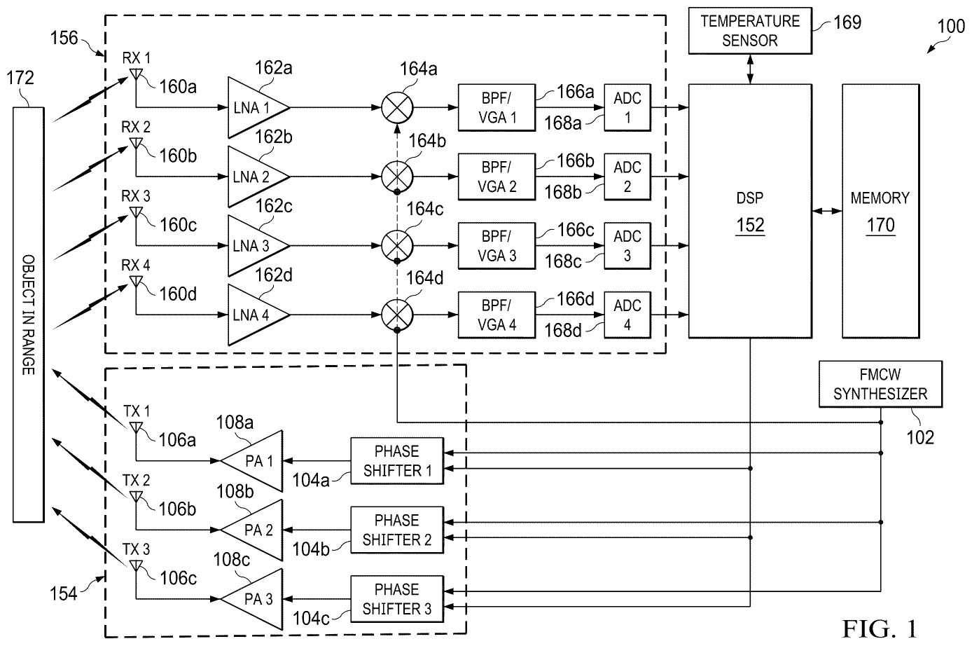

Turning to the figures, FIG. 1 is a block diagram of a first example system 100 that includes example phase shifters that may be implemented using example phase shifter circuit architectures described herein. The system 100 corresponds to an example Doppler division multiple access (DDMA) frequency modulated continuous wave (FMCW) radar system. The DDMA FMCW radar system 100 is a type of MIMO radar system. In a MIMO radar system with a number N transmitters and a number M receivers, if the N signals transmitted by the transmitters are predictable and different across different transmitters, yielding unique Doppler shifts per transmitter, then N different signals can be extracted from each of the signals received by the M receivers, resulting in N×M different received signals, as if the MIMO radar system had N×M different receivers. This enables improved spatial resolution of the radar system. Doppler differentiation can be used to make the N transmitted signals predictable and unique using phase shift vectors that are differentiated from each other in slow time.

The example FMCW radar system 100 includes an FMCW synthesizer 102, a digital signal processor (DSP) 152, a transmitter side 154, a receiver side 156, a temperature sensor 169, and a memory 170. The transmitter side 154 of the FMCW radar system 150 includes a first phase shifter (phase shifter 1) 104a, a second phase shifter (phase shifter 2) 104b, and a third phase shifter (phase shifter 3) 104c; a first power amplifier (PA1) 158a, a second power amplifier (PA2) 158b, and a third power amplifier (PA3) 158c; and a first transmitter (TX1) 106a, a second transmitter (TX2) 106b, and a third transmitter (TX3) 106c. The receiver side 156 of the FMCW radar system 100 includes a first receiver (RX1) 160a, a second receiver (RX2) 160b, a third receiver (RX3) 160c, and a fourth receiver (RX4) 160d; a first low noise amplifier (LNA1) 162a, a second low noise amplifier (LNA2) 162b, a third low noise amplifier (LNA3) 162c, and a fourth low noise amplifier (LNA4) 162d; a first mixer 164a, a second mixer 164b, a third mixer 164c, and a fourth mixer 164d; a first band pass filter (BPF) and variable gain amplifier (VGA) block (BPF/VGA 1) 166a, a second BPF and VGA block (BPF/VGA 2) 166b, a third BPF and VGA block (BPF/VGA 3) 166c, and a fourth BPF and VGA block (BPF/VGA 4) 166d; a first analog-to-digital converter (ADC) block (ADC 1) 168a, a second ADC block (ADC 2) 168b, a third ADC block (ADC 3) 168c, and a fourth ADC block (ADC 4) 168d.

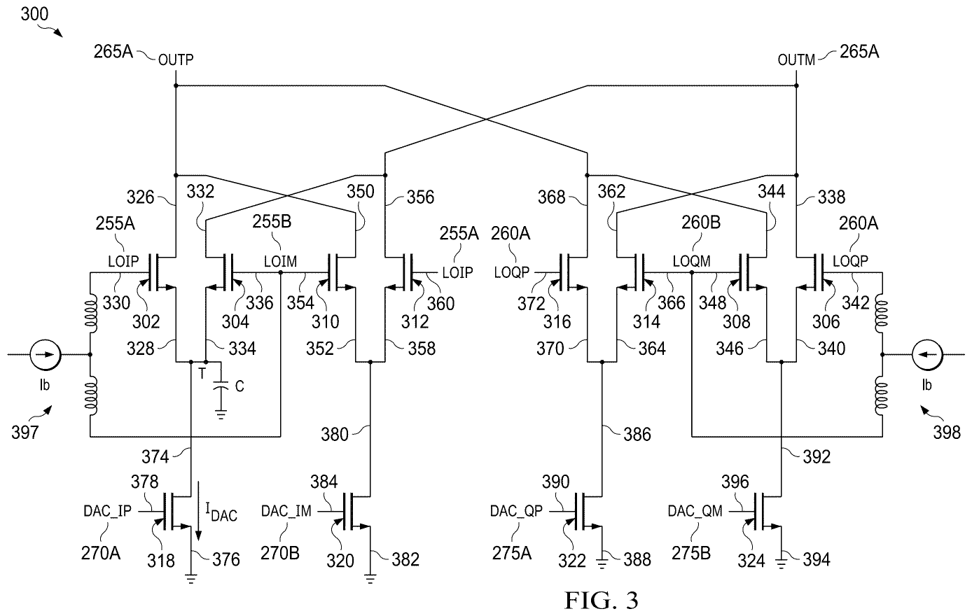

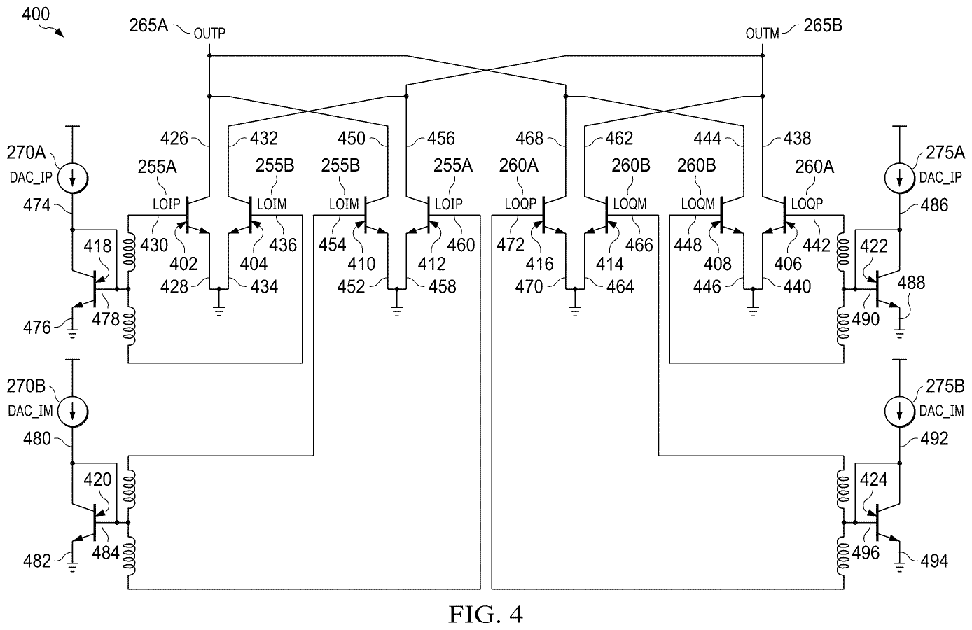

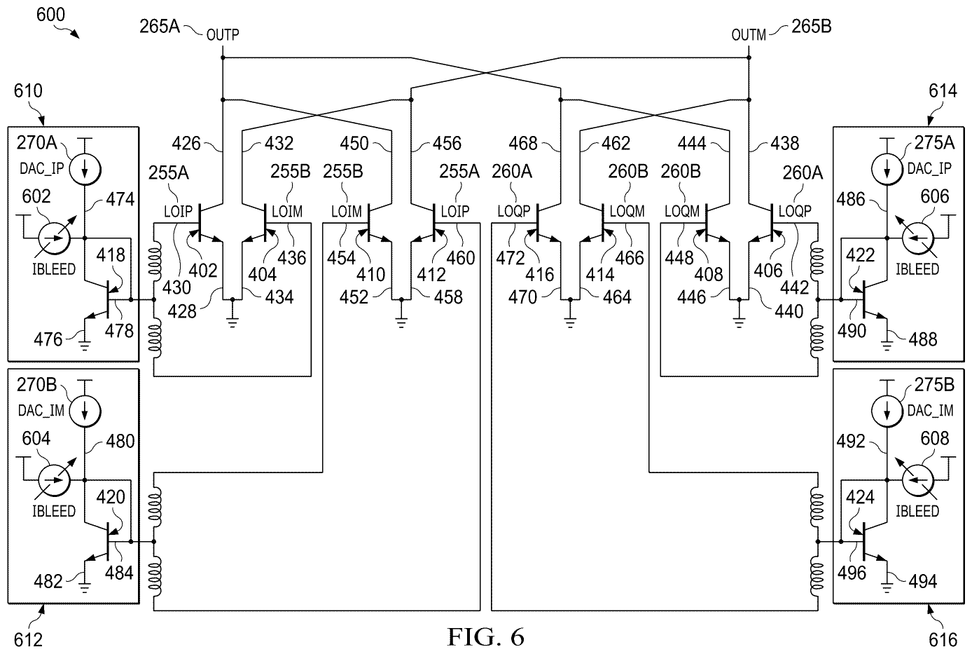

The FMCW synthesizer 102 generates FMCW chirps to be transmitted, such as for object detection and range, angle, and velocity determination. The FMCW synthesizer 102 outputs the FMCW chirps to respective first inputs of the first, second, and third phase shifters 104a, 104b, and 104c, and also to respective first inputs of the first, second, third, and fourth mixers 164a, 164b, 164c, and 164d. In some examples, the first, second, and third phase shifters 104a, 104b, and 104c are implemented by the example phase shifter circuit 300 of FIG. 3, the example phase shifter circuit 400 of FIG. 4 or the example phase shifter circuit 600 of FIG. 6.

In the DDMA FMCW radar system 100, the first, second, and third phase shifters 104a, 104b, and 104c phase shift the FMCW chirps using respective phase shift code vectors. In some examples, a phase shift coding has sixty-four possible code settings, from zero to sixty-three, representing zero radians to 2π*63/64^{ths} radians. Example phase shift code vectors include a first phase shift code vector of [0 16 32 48 0 16 32 48 0] and a second phase shift code vector of [0 24 48 8 32 56 16 40 0]. The first phase shift code vector increments by 16, and the second coding vector increments by 24.

However, actual phase shifter outputs may vary from ideal phase shifter outputs due to error introduced or propagated by the phase shifter. As described above, integral non-linearity (INL) error can be used to represent the difference between an ideal phase shift in a signal output by a phase shifter, and an actual phase shift in the signal output by the phase shifter. A phase shifter can have different INL errors for different phase shift codes. Further, the first phase shifter 104a, the second phase shifter 104b, and the third phase shifter 104c can respectively have different first, second, and third INL errors corresponding to a particular phase shift code. In some examples, phase shifter INL error varies with temperature.

The first, second, and third phase shifters 104a, 104b, and 104c output the FMCW chirps to, respectively, the first, second, and third power amplifiers PA1 158a, PA2 158b, and PA3 158c. The first, second, and third power amplifiers PA1 158a, PA2 158b, and PA3 158c amplify the respective phase shifted FMCW chirp signals, and output the amplified signals to, respectively, the first, second, and third transmitters 106a, 106b, and 106c. The first, second, and third transmitters 106a, 106b, and 106c transmit the amplified, phase shifted FMCW chirps. In some examples, the transmitted signals are reflected by an object 172 that is within the detection and range, angle, and velocity determination range of the FMCW radar system 100 (object in range 172).

The reflected signals are received by the first, second, third, and fourth receivers 160a, 160b, 160c, and 160d. The first, second, third, and fourth receivers 160a, 160b, 160c, and 160d output the received signals to, respectively, the first, second, third, and fourth low noise amplifiers LNA1 162a, LNA2 162b, LNA3 162c, and LNA4 162d, which amplify the received signals. The first, second, third, and fourth low noise amplifiers LNA1 162a, LNA1 162b, LNA1 162c, and LNA4 162d output the amplified signals to second inputs of, respectively, the first, second, third, and fourth mixers 164a, 164b, 164c, and 164d. The first, second, third, and fourth mixers 164a, 164b, 164c, and 164d output the mixed signals to, respectively, the first, second, third, and fourth BPF/VGA blocks 166a, 166b, 166c, and 166d, which filter and amplify the mixed signals. The first, second, third, and fourth BPF/VGA blocks 166a, 166b, 166c, and 166d output the resulting cleaned signals to, respectively, the first, second, third, and fourth ADC blocks 168a, 168b, 168c, and 168d, which sample the cleaned mixed signals to generate respective data sets made up of digital samples. The first, second, third, and fourth ADC blocks 168a, 168b, 168c, and 168d output the digital samples to the DSP 152 for analysis.

The DSP 152 uses the digital samples to determine presence, range, angle, and velocity of the object in range 172. For example, presence of an object may be determined based on a signal amplitude greater than a threshold. Range may be determined by a unique range frequency corresponding to the signal's round trip delay multiplied by the FMCW chirp slope. Velocity may be determined by the phase variation of the unique range frequency over multiple chirps, which manifests as a unique Doppler frequency. Angle may be determined by the phase variation for a particular received chirp across different receivers, caused by the difference in time of flight across the different receivers.

Phase shifter INL errors can cause false Doppler shift peaks (also caused spurs) in DSP 152 analysis results, potentially adversely affecting accuracy of angle and velocity determinations. For example, Doppler shift spurs may be interpreted as ghost targets-detected objects that are not actually present. Further, false Doppler shift peaks corresponding to one transmitter (such as the first, second, or third transmitter 106a, 106b, or 106c) can overlap with true Doppler shift peaks corresponding to another transmitter, distorting results. This is referred to as inter-transmitter coupling. In some examples, the first, second, and third phase shifters 104a, 104b, and 104c are implemented by the example phase shifter circuit 400 of FIG. 4 or the example phase shifter circuit 600 of FIG. 6 to reduce the phase shifter INL errors.

In the illustrated example, the temperature sensor 169 measures ambient temperature and provides temperature information to the DSP 152. In some examples, the DSP 152 adjusts the phase shifts applied by the first, second, and third phase shifters 104a, 104b, and 104c based on the measured temperature. For example, the DSP 152 may configure one or more programmable bleed current sources of the first, second, and third phase shifters 104a, 104b, and 104c to bias the phase shift input signals based on temperature-dependent configuration information stored in the memory 170.

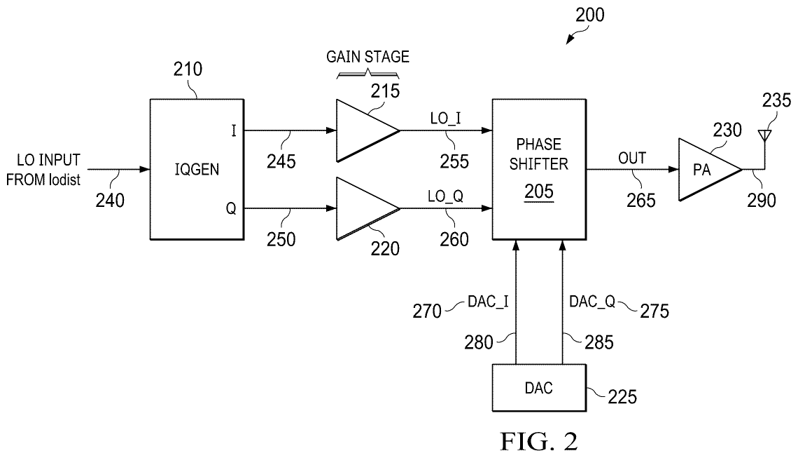

FIG. 2 is a block diagram of a second example system 200 that includes an example phase shifter 205 that may be implemented using example phase shifter circuit architectures described herein. The system 200 may be used to implement a radar system, a communication system, etc. The system 200 includes the phase shifter 205, an example signal generator 210, example gain stage amplifiers 215 and 220, an example DAC 225, an example power amplifier (PA) 230 and an example antenna 235.

The signal generator 210 of the illustrated example has an example source signal input 240, and example in-phase source signal output 245 and an example quadrature source signal output 250. The signal generator 210 operates to generate an in-phase component and a quadrature component of a source signal provided to the source signal input 240. The source signal can be a radio frequency (RF) signal, an intermediate frequency (IF) signal or any other input signal. As shown in the example of FIG. 2, the source signal is generated based on a local oscillator of the system 200. The signal generator 210 outputs the in-phase source component signal and the quadrature source component signal at the in-phase source signal output 245 and the quadrature source signal output 250, respectively. In some examples, the in-phase source signal output 245 and the quadrature source signal output 250 are differential outputs that include respective pairs of non-inverted (e.g., “+”) outputs and inverted (“−”) outputs.

The gain stage amplifier 215 of the illustrated example applies a gain (e.g., an amplification, an attenuation, etc.) to the in-phase source component signal produced at the in-phase source signal output 245. The gain stage amplifier 220 of the illustrated example applies a gain (e.g., an amplification, an attenuation, etc.) to the quadrature source component signal produced at the quadrature source signal output 250.

The phase shifter 205 of the illustrated example includes an example in-phase source input 255, an example quadrature source input 260 and an example phase shifter output 265. The in-phase source input 255 accepts the in-phase source component signal produced at the in-phase source signal output 245 and processed by the gain stage amplifier 215. Likewise, the quadrature source input 260 accepts the quadrature source component signal produced at the quadrature source signal output 250 and processed by the gain stage amplifier 220. As such, in some examples, the in-phase source input 255 and the quadrature source input 260 are differential inputs that include respective pairs of non-inverted (e.g., “+”) inputs and inverted (“−”) inputs. The phase shifter 205 operates to apply a phase shift to the in-phase source component signal and the quadrature source component signal applied to the in-phase source input 255 and the quadrature source signal output 250 to produce an output signal at the phase shifter output 265 with the applied phase shift.

As such, the phase shifter 205 of the illustrated example also includes an example in-phase phase shift input 270 and an example quadrature phase shift input 275 to accept input signals that specify or otherwise correspond to the phase shift to be applied to the input signal applied to the in-phase source input 255 and the quadrature source input 260. In the illustrated example, the in-phase phase shift input 270 and the quadrature phase shift input 275 are configurable to be coupled respectively to a corresponding example in-phase DAC output 280 and a corresponding example quadrature DAC output 285 of the DAC 225. In some examples, the in-phase phase shift input 270 and the quadrature phase shift input 275 are differential inputs that include respective pairs of non-inverted (e.g., “+”) inputs and inverted (“−”) inputs. Likewise, in some examples, the in-phase DAC output 280 and the quadrature DAC output 285 are differential outputs that include respective pairs of non-inverted (e.g., “+”) inputs and inverted (“−”) outputs.

In the illustrated example, the DAC 225 is configured to output signals at its in-phase DAC output 280 and the quadrature DAC output 285 that correspond to the in-phase and quadrature components, respectively, of the configured phase shift that is to be applied by the phase shifter 205. For example, let the signal output by the DAC 225 at its in-phase DAC output 280 be represented by DAC_I, and let the signal output by the DAC 225 at its quadrature DAC output 285 be DAC_Q. In some such examples, the resulting phase shift corresponding to the phase shift signal values DAC_I and DAC_Q is, or can be approximated by, Equation 1, which is:

$$Phase shift = {tan}^{- 1} ( \frac{DAC\_Q}{DAC\_I} ) \qquad Equation 1$$

Thus, in some such examples, the DAC 225 outputs in-phase and quadrature phase shift signals at its in-phase DAC output 280 and its quadrature DAC output 285, respectively, to configure the phase shifter 205 to apply a phase shift corresponding to Equation 1.

In the illustrated example, the PA 230 amplifies the phase-shifted output signal provided at the output 265 of the phase shifter 205 to produce an example transmit signal 290 with the applied phase shift. The transmit signal 290 is transmitted via the antenna 235.

FIG. 3 is a block diagram of a first example phase shifter circuit 300 that may be used to implement the phase shifters in the example system 100 of FIG. 1 and/or the example system 200 of FIG. 2. The phase shifter circuit 300 of the illustrated example includes example differential in-phase source inputs 255A-B, example differential quadrature source inputs 260A-B, example differential phase shifter outputs 265A-B, example in-phase phase shift inputs 270A-B and example quadrature phase shift inputs 275A-B. The in-phase source inputs 255A-B, the differential quadrature source inputs 260A-B, the differential phase shifter outputs 265A-B, the in-phase phase shift inputs 270A-B and the quadrature phase shift inputs 275A-B are differential versions of the in-phase source input 255, the differential quadrature source input 260, the differential phase shifter output 265, the in-phase phase shift input 270 and the quadrature phase shift input 275, respectively, in the system of FIG. 2. As such, the differential in-phase source inputs 255A-B are respective non-inverted and inverted inputs, the differential quadrature source inputs 260A-B are respective non-inverted and inverted inputs, the differential phase shifter outputs 265A-B are respective non-inverted and inverted outputs, the in-phase phase shift inputs 270A-B are respective non-inverted and inverted inputs, and the quadrature phase shift inputs 275A-B are respective non-inverted and inverted inputs. Furthermore, the differential in-phase source inputs 255A-B are configurable to be coupled to the gain stage amplifier 215 and/or the in-phase source signal output 245 of the signal generator 210, the differential quadrature source inputs 260A-B are configurable to be coupled to the gain stage amplifier 220 and/or the quadrature source signal output 250 of the signal generator 210, the differential phase shifter outputs 265A-B are configurable to be coupled to the power amplifier 230, the in-phase phase shift inputs 270A-B are configurable to be coupled to the in-phase DAC output 280 of the DAC 225, and the quadrature phase shift inputs 275A-B are configurable to be coupled to the quadrature DAC output 280 of the DAC 225.

The phase shifter circuit 300 of the illustrated example is based on a Gilbert cell circuit architecture that performs a complex multiplication of (i) the in-phase and quadrature source signals applied to the differential in-phase source inputs 255A-B and the differential quadrature source inputs 260A-B, respectively, with (ii) the in-phase and quadrature phase shift signals applied to the in-phase phase shift inputs 270A-B and the quadrature phase shift inputs 275A-B, respectively, to produce (iii) a phase-shifted output signal at the phase shifter outputs 265A-B. The phase-shifted output signal produced at the phase shifter outputs 265A-B corresponds to the input source signal but having a phase shift corresponding to the input phase shift signal.

The phase shifter circuit 300 includes example transistors 302-324 that are arranged to form the Gilbert cell circuit architecture. In the illustrated example of FIG. 3, a first example transistor 302 and a second example transistor 304 form a first transistor pair to accept the in-phase source signals applied to the differential in-phase source inputs 255A-B. In the illustrated example of FIG. 3, a third example transistor 306 and a fourth example transistor 308 form a second transistor pair to accept the quadrature source signals applied to the differential quadrature source inputs 260A-B. In the illustrated example of FIG. 3, a fifth example transistor 310 and a sixth example transistor 312 form a third transistor pair to accept the in-phase source signals applied to the differential in-phase source inputs 255A-B. In the illustrated example of FIG. 3, a seventh example transistor 314 and an eighth example transistor 316 form a fourth transistor pair to accept the quadrature source signals applied to the differential quadrature source inputs 260A-B. In the illustrated example of FIG. 3, a ninth example transistor 318 and a tenth example transistor 320 form a fifth transistor pair to accept the in-phase phase shift signal applied to the in-phase phase shift inputs 270A-B, and an eleventh example transistor 322 and a twelfth example transistor 324 form a sixth transistor pair to accept the quadrature phase shift signal applied to the quadrature phase shift inputs 275A-B.

More specifically, the first example transistor 302 includes a first load terminal 326, a second load terminal 328 and a first control terminal 330. The second example transistor 304 includes a third load terminal 332, a fourth load terminal 334 and a second control terminal 336. The third example transistor 306 includes a fifth load terminal 338, a sixth load terminal 340 and a third control terminal 342. The fourth example transistor 308 includes a seventh load terminal 344, an eighth load terminal 346 and a fourth control terminal 348. The fifth example transistor 310 includes a ninth load terminal 350, a tenth load terminal 352 and a fifth control terminal 354. The sixth example transistor 312 includes an eleventh load terminal 356, a twelfth load terminal 358 and a sixth control terminal 360. The seventh example transistor 314 includes a thirteenth load terminal 362, a fourteenth load terminal 364 and a seventh control terminal 366. The eighth example transistor 316 includes a fifteenth load terminal 368, a sixteenth load terminal 370 and an eighth control terminal 372. The ninth example transistor 318 includes a seventeenth load terminal 374, an eighteenth load terminal 376 and a ninth control terminal 378. The tenth example transistor 320 includes a nineteenth load terminal 380, twentieth load terminal 382 and a tenth control terminal 384. The eleventh example transistor 322 includes a twenty-first load terminal 386, a twenty-second load terminal 388 and an eleventh control terminal 390. The twelfth example transistor 324 includes a twenty-third load terminal 392, a twenty-fourth load terminal 394 and a twelfth control terminal 396.

In the phase shifter circuit 300 of FIG. 3, the transistors 302-324 are p-channel field-effect transistors (FETs), such as p-channel metal-oxide semiconductor field-effect transistors (MOSFETs), p-channel junction field effect transistors (JFETs), etc. Thus, in the illustrated example, the first load terminal 326, the third load terminal 332, the fifth load terminal 338, the seventh load terminal 344, the ninth load terminal 350, the eleventh load terminal 356, the thirteenth load terminal 362, the fifteenth load terminal 368, the seventeenth load terminal 374, the nineteenth load terminal 380, the twenty-first load terminal 386, and the twenty-third load terminal 392 are respective drain terminals of the transistors 302-324. Also, in the illustrated example, the second load terminal 328, the fourth load terminal 334, the sixth load terminal 340, the eighth load terminal 346, the tenth load terminal 352, the twelfth load terminal 358, the fourteenth load terminal 364, the sixteenth load terminal 370, the eighteenth load terminal 376, the twentieth load terminal 382, the twenty-second load terminal, 388 and the twenty-fourth load terminal 394 are respective source terminals of the transistors 302-324. Further, in the illustrated example, the first control terminal 330, the second control terminal 336, the third control terminal 342, the fourth control terminal 348, the fifth control terminal 354, the sixth control terminal 360, the seventh control terminal 366, the eighth control terminal 372, the ninth control terminal 378, the tenth control terminal 384, the eleventh control terminal 390, and the twelfth control terminal 396 are respective gate terminals of the transistors 302-324.

However, in some examples, the transistors 302-324 may be p-channel IGBTs, PNP bipolar junction transistors (BJTs), or, with slight modifications, N-type equivalent devices. In some examples, the transistors 302-324 may be depletion mode devices, drain-extended devices, enhancement mode devices, natural transistors or other type of device structure transistors. In some examples, the transistors 302-324 may be implemented in/over a silicon substrate (Si), a silicon carbide substrate (SiC), a gallium nitride substrate (GaN) or a gallium arsenide substrate (GaAs).

In the phase shifter circuit 300 of FIG. 3, the transistors 302-316 are referred to as source signal transistors 302-316 (or local oscillator transistors 302-316) because those transistors receive or otherwise accept the input source signal to which a configured phase shift is to be applied. In the phase shifter circuit 300 of FIG. 3, the first control terminal 330 of the source signal transistor 302 and the sixth control terminal 360 of the source signal transistor 312 are coupled to the non-inverting in-phase source input 255A, and the second control terminal 336 of the source signal transistor 304 and the fifth control terminal 354 of the source signal transistor 310 are coupled to the inverting in-phase source input 255B. Likewise, in the phase shifter circuit 300 of FIG. 3, the third control terminal 342 of the source signal transistor 306 and the eighth control terminal 372 of the source signal transistor 316 are to form the non-inverting quadrature source input 260A, and the fourth control terminal 348 of the source signal transistor 308 and the seventh control terminal 366 of the source signal transistor 314 are coupled to the inverting quadrature source input 260B. The phase shifter circuit 300 also includes example bias circuits 397 and 398 to apply bias currents to the transistors 302-316, as shown in FIG. 3.

In the phase shifter circuit 300 of FIG. 3, the first load terminal 326, the third load terminal 332, the fifth load terminal 338, the seventh load terminal 344, the ninth load terminal 350, the eleventh load terminal 356, the thirteenth load terminal 362 and the fifteenth load terminal 368 of the source signal transistors 302-316 are cross-coupled to the differential phase shifter outputs 265A-B. More specifically, the first load terminal 326, the seventh load terminal 344, the ninth load terminal 350 and the fifteenth load terminal 368 are coupled to the non-inverting phase shifter output 265A, and the third load terminal 332, the fifth load terminal 338, the eleventh load terminal 356 and the thirteenth load terminal 362 are coupled to the inverting phase shifter output 265B.

In the phase shifter circuit 300 of FIG. 3, the transistors 318-324 are referred to as the phase shift transistors 318-324 (or the DAC transistors 318-324) because those transistors receive or otherwise accept the phase shift signals from the DAC 225 that correspond to the configured phase shift to be applied to the input source signal. In the phase shifter circuit 300 of FIG. 3, the ninth control terminal 378 of the phase shift transistor 318 is coupled to the non-inverting in-phase phase shift input 270A, and the tenth control terminal 384 of the phase shift transistor 320 is coupled to the inverting quadrature phase input 270B. Likewise, in the phase shifter circuit 300 of FIG. 3, the eleventh control terminal 390 of the phase shift transistor 322 is coupled to the non-inverting quadrature phase shift input 275A, and the twelfth control terminal 396 of the phase shift transistor 324 is coupled to the inverting quadrature source input 275B. In the phase shifter circuit 300 of FIG. 3, the eighteenth load terminal 376, the twentieth load terminal 382, twenty-second load terminal 388 and the twenty-fourth load terminal 394 of the phase shift transistors 318-324 (or the DAC transistors 318-324), respectively, are coupled to one or more ground circuit node(s) or other low-impedance circuit node(s).

In the phase shifter circuit 300 of FIG. 3, to couple the source signal transistors 302-316 (or local oscillator transistors 302-316) with the phase shift transistors 318-324 (or the DAC transistors 318-324), (i) the second load terminal 328 of the source signal transistor 302, the fourth load terminal 334 of the source signal transistor 304 and the seventeenth load terminal 374 of the phase shift transistor 318 are coupled together, (ii) the sixth load terminal 340 of the source signal transistor 306, the eighth load terminal 346 of the source signal transistor 308 and the twenty-third load terminal 392 of the phase shift transistor 324 are coupled together, (iii) the tenth load terminal 352 of the source signal transistor 310, the twelfth load terminal 358 of the source signal transistor 312 and the nineteenth load terminal 380 of the phase shift transistor 320 are coupled together, and (iv) the fourteenth load terminal 364 of the source signal transistor 314, the sixteenth load terminal 370 of the source signal transistor 316 and the twenty-first load terminal 386 of the phase shift transistor 322 are coupled together.

The phase shifter circuit 300 of the illustrated example has several potential drawbacks. First, the available dynamic range of the phase shift transistors 318-324 (or the DAC transistors 318-324) is reduced (e.g., crunched) relative to the full dynamic range of the transistors by the bias voltages of the source signal transistors 302-316 (or local oscillator transistors 302-316). For example, with reference to the phase shift transistor 318 and the source signal transistor 302, the bias voltage from the control terminal 330 to the load terminal 328 of the source signal transistor 302 is inversely related to the size of the source signal transistor 302, and there may be an upper limit on the transistor size, which places a lower limit on the bias voltage. As such, the available dynamic range across the load terminals of the phase shift transistor 318 (e.g., at the node labelled “T” in FIG. 3) has an upper limit (e.g., headroom) that is reduced by the bias voltage of the source signal transistor 302. Furthermore, there may be a lower limit on the required current through the source signal transistor 302 that is dictated by the uncorrelated phase noise (UPN) of the phase shifter circuit 300, which further reduces the available dynamic range across the load terminals of the phase shift transistor 318. Such a dynamic range reduction across the load terminals of the phase shift transistor 318 can degrade the INL of the phase shifter circuit 300.

Second, the voltage swings at the nodes coupling the phase shift transistors 318-324 (or the DAC transistors 318-324) to the source signal transistors 302-316 (or local oscillator transistors 302-316) can degrade the INL of the phase shifter circuit 300. For example, with reference to the phase shift transistor 318 and the source signal transistor 302, voltage swings at the node labelled “T” in FIG. 3 can also reduce (e.g., crunch) the available dynamic range (e.g., headroom) of the phase shift transistor 318. Also, the node T may not be tuned to reduce passive area and to increase vector modulation gain, resulting in a parasitic capacitance to ground (labelled “Cp” in FIG. 3), which shunts current and degrades INL. Furthermore, the source signal transistors 302-316 act as respective switching pairs, and the phase shift transistors 318-324 operate as degeneration loads and reduce gain.

Third, the INL of the phase shifter circuit 300 is also affected by the intrinsic device nonlinearities of the source signal transistors 302-316 (or local oscillator transistors 302-316) and the phase shift transistors 318-324 (or the DAC transistors 318-324). However, the Gilbert cell circuit architecture of the phase shifter circuit 300 does not provide a straightforward way to mitigate those nonlinearities.

FIG. 4 is a block diagram of a second example phase shifter circuit 400 that may be used to implement the phase shifters in the example system 100 of FIG. 1 and/or the example system 200 of FIG. 2. The second phase shifter circuit 400 is designed to overcome at least some of the drawbacks of the first phase shifter circuit 300 described above. Like the first phase shifter circuit 300, the second phase shifter circuit 400 of the illustrated example includes the differential in-phase source inputs 255A-B, the differential quadrature source inputs 260A-B, the differential phase shifter outputs 265A-B, the in-phase phase shift inputs 270A-B and the quadrature phase shift inputs 275A-B. As described above, the in-phase source inputs 255A-B, the differential quadrature source inputs 260A-B, the differential phase shifter outputs 265A-B, the in-phase phase shift inputs 270A-B and the quadrature phase shift inputs 275A-B are differential versions of the in-phase source input 255, the differential quadrature source input 260, the differential phase shifter output 265, the in-phase phase shift input 270 and the quadrature phase shift input 275, respectively, in the system of FIG. 2. As such, the differential in-phase source inputs 255A-B are respective non-inverted and inverted inputs, the differential quadrature source inputs 260A-B are respective non-inverted and inverted inputs, the differential phase shifter outputs 265A-B are respective non-inverted and inverted outputs, the in-phase phase shift inputs 270A-B are respective non-inverted and inverted inputs, and the quadrature phase shift inputs 275A-B are respective non-inverted and inverted inputs. Furthermore, the differential in-phase source inputs 255A-B are configurable to be coupled to the gain stage amplifier 215 and/or the in-phase source signal output 245 of the signal generator 210, the differential quadrature source inputs 260A-B are configurable to be coupled to the gain stage amplifier 220 and/or the quadrature source signal output 250 of the signal generator 210, the differential phase shifter outputs 265A-B are configurable to be coupled to the power amplifier 230, the in-phase phase shift inputs 270A-B are configurable to be coupled to the in-phase DAC output 280 of the DAC 225, and the quadrature phase shift inputs 275A-B are configurable to be coupled to the quadrature DAC output 280 of the DAC 225.

The phase shifter circuit 400 of the illustrated example is based on a modified Gilbert cell circuit architecture that performs a complex multiplication of (i) the in-phase and quadrature source signals applied to the differential in-phase source inputs 255A-B and the differential quadrature source inputs 260A-B, respectively, with (ii) the in-phase and quadrature phase shift signals applied to the in-phase phase shift inputs 270A-B and the quadrature phase shift inputs 275A-B, respectively, to produce (iii) a phase-shifted output signal at the phase shifter outputs 265A-B. The phase-shifted output signal produced at the phase shifter outputs 265A-B corresponds to the input source signal but having a phase shift corresponding to the input phase shift signal.

The phase shifter circuit 400 includes example transistors 402-424 that are arranged to form the modified Gilbert cell circuit architecture. In the illustrated example of FIG. 4, a first example transistor 402 and a second example transistor 404 form a first transistor pair to accept the in-phase source signals applied to the differential in-phase source inputs 255A-B. In the illustrated example of FIG. 4, a third example transistor 406 and a fourth example transistor 408 form a second transistor pair to accept the quadrature source signals applied to the differential quadrature source inputs 260A-B. In the illustrated example of FIG. 4, a fifth example transistor 410 and a sixth example transistor 412 form a third transistor pair to accept the in-phase source signals applied to the differential in-phase source inputs 255A-B. In the illustrated example of FIG. 4, a seventh example transistor 414 and an eighth example transistor 416 form a fourth transistor pair to accept the quadrature source signals applied to the differential quadrature source inputs 260A-B. In the illustrated example of FIG. 4, a ninth example transistor 418 and a tenth example transistor 420 form a fifth transistor pair to accept the in-phase phase shift signal applied to the in-phase phase shift inputs 270A-B, and an eleventh example transistor 422 and a twelfth example transistor 424 form a sixth transistor pair to accept the quadrature phase shift signal applied to the quadrature phase shift inputs 275A-B.

More specifically, the first example transistor 402 includes a first load terminal 426, a second load terminal 428 and a first control terminal 430. The second example transistor 404 includes a third load terminal 432, a fourth load terminal 434 and a second control terminal 436. The third example transistor 406 includes a fifth load terminal 438, a sixth load terminal 440 and a third control terminal 442. The fourth example transistor 408 includes a seventh load terminal 444, an eighth load terminal 446 and a fourth control terminal 448. The fifth example transistor 410 includes a ninth load terminal 450, a tenth load terminal 452 and a fifth control terminal 454. The sixth example transistor 412 includes an eleventh load terminal 456, a twelfth load terminal 458 and a sixth control terminal 460. The seventh example transistor 414 includes a thirteenth load terminal 462, a fourteenth load terminal 464 and a seventh control terminal 466. The eighth example transistor 416 includes a fifteenth load terminal 468, a sixteenth load terminal 470 and an eighth control terminal 472. The ninth example transistor 418 includes a seventeenth load terminal 474, an eighteenth load terminal 476 and a ninth control terminal 478. The tenth example transistor 420 includes a nineteenth load terminal 480, twentieth load terminal 482 and a tenth control terminal 484. The eleventh example transistor 422 includes a twenty-first load terminal 486, a twenty-second load terminal 488 and an eleventh control terminal 490. The twelfth example transistor 424 includes twenty-third load terminal 492, a twenty-fourth load terminal 494 and a twelfth control terminal 496.

In the phase shifter circuit 400 of FIG. 4, the transistors 402-424 are NPN BJTs. Thus, in the illustrated example, the first load terminal 426, the third load terminal 432, the fifth load terminal 438, the seventh load terminal 444, the ninth load terminal 450, the eleventh load terminal 456, the thirteenth load terminal 462, the fifteenth load terminal 468, the seventeenth load terminal 474, the nineteenth load terminal 480, the twenty-first load terminal 486, and the twenty-third load terminal 492 are respective collector terminals of the transistors 402-424. Also, in the illustrated example, the second load terminal 428, the fourth load terminal 434, the sixth load terminal 440, the eighth load terminal 446, the tenth load terminal 452, the twelfth load terminal 458, the fourteenth load terminal 464, the sixteenth load terminal 470, the eighteenth load terminal 476, the twentieth load terminal 482, the twenty-second load terminal, 488 and the twenty-fourth load terminal 494 are respective emitter terminals of the transistors 402-424. Further, in the illustrated example, the first control terminal 430, the second control terminal 436, the third control terminal 442, the fourth control terminal 448, the fifth control terminal 454, the sixth control terminal 460, the seventh control terminal 466, the eighth control terminal 472, the ninth control terminal 478, the tenth control terminal 484, the eleventh control terminal 490, and the twelfth control terminal 496 are respective base terminals of the transistors 402-424.

However, in some examples, the transistors 402-424 may be n-channel FETs, such as n-channel MOSFETs, n-channel JFETs, etc., or n-channel IGBTs or, with slight modifications, P-type equivalent devices. In some examples, the transistors 402-424 may be depletion mode devices, drain-extended devices, enhancement mode devices, natural transistors or other type of device structure transistors. In some examples, the transistors 402-424 may be implemented in/over a silicon substrate (Si), a silicon carbide substrate (SiC), a gallium nitride substrate (GaN) or a gallium arsenide substrate (GaAs).

In the phase shifter circuit 400 of FIG. 4, the transistors 402-416 are referred to as source signal transistors 402-416 (or local oscillator transistors 402-416) because those transistors receive or otherwise accept the input source signal to which a configured phase shift is to be applied. In the phase shifter circuit 400 of FIG. 4, the first control terminal 430 of the source signal transistor 402 and the sixth control terminal 460 of the source signal transistor 412 are coupled to the non-inverting in-phase source input 255A, and the second control terminal 436 of the source signal transistor 404 and the fifth control terminal 454 of the source signal transistor 410 are coupled to the inverting in-phase source input 255B. Likewise, in the phase shifter circuit 400 of FIG. 4, the third control terminal 442 of the source signal transistor 406 and the eighth control terminal 472 of the source signal transistor 416 are coupled to the non-inverting quadrature source input 260A, and the fourth control terminal 448 of the source signal transistor 408 and the seventh control terminal 466 of the source signal transistor 414 are coupled to the inverting quadrature source input 260B.

In the phase shifter circuit 400 of FIG. 4, the first load terminal 426, the third load terminal 432, the fifth load terminal 438, the seventh load terminal 444, the ninth load terminal 450, the eleventh load terminal 456, the thirteenth load terminal 462 and the fifteenth load terminal 468 of the source signal transistors 402-416 are cross-coupled to the differential phase shifter outputs 265A-B. More specifically, the first load terminal 426, the seventh load terminal 444, the ninth load terminal 450 and the fifteenth load terminal 468 are coupled to the non-inverting phase shifter output 265A, and the third load terminal 432, the fifth load terminal 438, the eleventh load terminal 456 and the thirteenth load terminal 462 are coupled to the inverting phase shifter output 265B.

Unlike in the phase shifter circuit 300, in the phase shifter circuit 400 of FIG. 4, the second load terminal 428, the fourth load terminal 434, the sixth load terminal 440, the eighth load terminal 446, the tenth load terminal 452, the twelfth load terminal 458, the fourteenth load terminal 464, and the sixteenth load terminal 470 of the source signal transistors 402-416 are coupled to one or more ground circuit node(s) or other low-impedance circuit node(s). Examples of low-impedance circuit nodes includes ground nodes, power supply nodes, voltage rails, and any other large voltage sinks or voltage sources. By coupling the second load terminal 428, the fourth load terminal 434, the sixth load terminal 440, the eighth load terminal 446, the tenth load terminal 452, the twelfth load terminal 458, the fourteenth load terminal 464, and the sixteenth load terminal 470 of the source signal transistors 402-416 to ground circuit node(s) or other low-impedance circuit node(s), the phase shifter circuit 400 reduces or eliminates the parasitic capacitance Cp that is a drawback of the phase shifter circuit 300, thereby improving INL and resolution of the phase shifter circuit 400 relative to the phase shifter circuit 300.

In the phase shifter circuit 400 of FIG. 4, the transistors 418-424 are referred to as the phase shift transistors 418-424 (or the DAC transistors 418-424) because those transistors receive or otherwise accept the phase shift signals from the DAC 225 that correspond to the configured phase shift to be applied to the input source signal. The phase shifter circuit 400 differs from the phase shifter circuit 300 in that there are no phase shift transistors coupled between the source signal transistors 402-416 and the ground node in the phase shifter circuit 400.

In the phase shifter circuit 400 of FIG. 4, the seventeenth load terminal 474 of the phase shift transistor 418 is coupled to the non-inverting in-phase phase shift input 270A, and the nineteenth load terminal 480 of the phase shift transistor 420 is coupled to the inverting quadrature phase input 270B. Likewise, in the phase shifter circuit 400 of FIG. 4, the twenty-first load terminal 486 of the phase shift transistor 422 is coupled to the non-inverting quadrature phase shift input 275A, and the twenty-third load terminal 492 of the phase shift transistor 424 is coupled to the inverting quadrature source input 275B. In the phase shifter circuit 400 of FIG. 4, the eighteenth load terminal 476, the twentieth load terminal 482, twenty-second load terminal 488 and the twenty-fourth load terminal 494 of the phase shift transistors 418-424 (or the DAC transistors 418-424), respectively, are coupled to one or more ground circuit node(s) or other low-impedance circuit node(s).

Furthermore, unlike in the phase shifter circuit 300, to couple the source signal transistors 402-416 (or local oscillator transistors 402-416) with the phase shift transistors 418-424 (or the DAC transistors 418-424) in the phase shifter circuit 400, the ninth control terminal 478 of the phase shift transistor 418 is coupled (e.g., inductively) with the first control terminal 430 of the source signal transistor 402 and the second control terminal 436 of the source signal transistor 404, the tenth control terminal 484 of the phase shift transistor 420 is coupled (e.g., inductively) to the fifth control terminal 454 of the source signal transistor 410 and the sixth control terminal 460 of the source signal transistor 412, the eleventh control terminal 490 of the phase shift transistor 422 is coupled (e.g., inductively) to the third control terminal 442 of the source signal transistor 406 and the fourth control terminal 448 of the source signal transistor 408, and the twelfth control terminal 496 of the phase shift transistor 424 is coupled (e.g., inductively) to the seventh control terminal 466 of the source signal transistor 410 and the eighth control terminal 472 of the source signal transistor 412. In this way, the circuit implemented by the phase shift transistor 418, the circuit implemented by the phase shift transistor 420, the circuit implemented by the phase shift transistor 422 and the circuit implemented by the phase shift transistor 424 provide not only the phase shift signals corresponding to the phase shift to be applied to the source signal, but also provide the bias currents for the source signal transistors 402-416, thereby allowing the bias circuits 397 and 398 of the phase shifter circuit 300 to be omitted from the phase shifter circuit 400 of FIG. 4.

Also, because the source signal transistors 402-416 are coupled to the phase shift transistors 418-424 by their respective control terminals as shown in FIG. 4, the dynamic range of the phase shift transistors 418-424 is not reduced (e.g., crunched) by the bias voltages of the source signal transistors 402-416. Thus, unlike the dynamic range of the phase shift transistors 318-324 in the phase shifter circuit 300, which is reduced (e.g., crunched) by the source signal transistors 302-316, the voltages across the load terminals of the respective phase shift transistors 418-424 of the phase shifter circuit 400 are able to span the full dynamic range of the transistors. As such, the phase shifter circuit 400 reduces or avoids this source of INL degradation that is present in the phase shifter circuit 400. In addition, the load terminals of the source signal transistors 402-416 are coupled directly to the phase shifter outputs 265A-B and the low-impedance node (e.g., the ground node). In contrast, the source signal transistors 302-316 shown in FIG. 3 are coupled in series with the phase shift transistors 318-324, resulting in a lower voltage drop across the load terminals of the source signal transistors 302-316 because the voltage is divided across the source signal transistors 302-316 and the phase shift transistors 318-324. A higher voltage drop across the load terminals can also reduce the INL degradation.

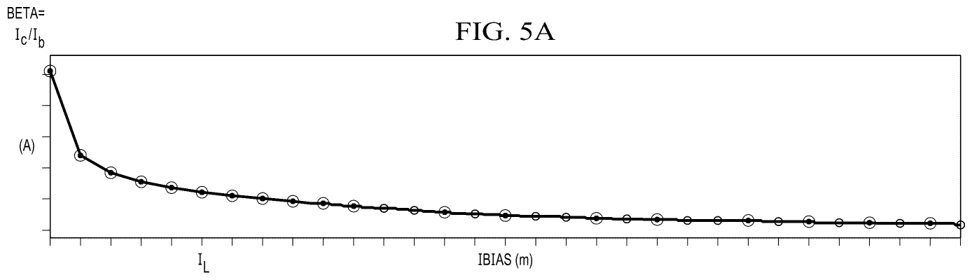

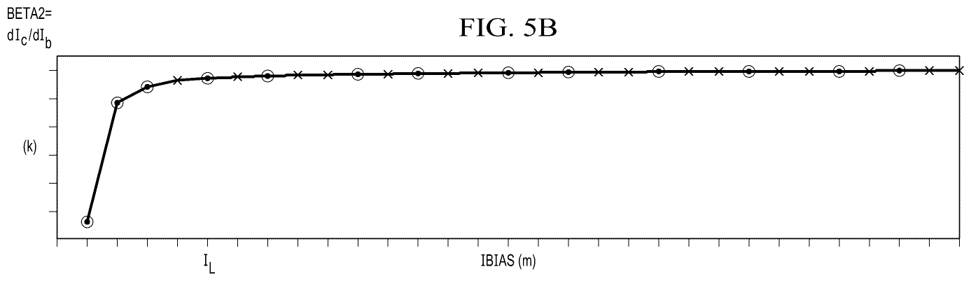

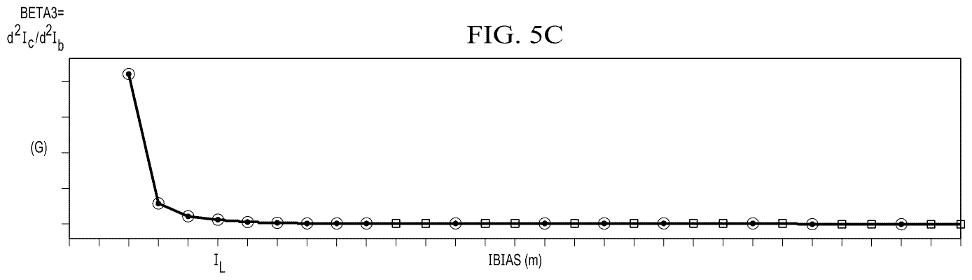

FIGS. 5A-5C illustrate example intrinsic nonlinear characteristics associated with the second example phase shifter 400 of FIG. 4. In particular, FIG. 5A illustrates an example graph 505 of the beta values of one of the phase shift transistors 418-424, such as the phase shift transistor 418, relative the bias current applied the phase shift transistor 418. The beta value of the phase shift transistor 418 is the ratio of the transistor's collector current, Ic, to its base current, Ib, for a given bias current. In other words, beta=Ic/Ib.

FIG. 5B illustrates an example graph 510 of the beta2 values of one of the phase shift transistors 418-424, such as the phase shift transistor 418, relative the bias current applied to the phase shift transistor 418. The beta2 value of the phase shift transistor 418 is the ratio of the derivative of the transistor's collector current, dIc, to the derivative of its base current, dIb, for a given bias current. In other words, beta2=dIc/dIb.

FIG. 5C illustrates an example graph 515 of the beta3 values of one of the phase shift transistors 418-424, such as the phase shift transistor 418, relative the bias current applied to the phase shift transistor 418. The beta3 value of the phase shift transistor 418 is the ratio of the second derivative of the transistor's collector current, d²Ic, to the second derivative of its base current, d²Ib, for a given bias current. In other words, beta3=d²Ic/d²Ib.

The graphs 505-515 illustrate that the beta, beta2 and beta3 values of the phase shift transistors 418-424 exhibit good linear behavior for bias current values greater than or equal to a threshold, such as greater than or equal to the threshold value represented by the variable I_{L} in the illustrated example of FIGS. 5A-5C. However, the beta, beta2 and beta3 values of the phase shift transistors 418-424 exhibit nonlinear behavior for bias current values less than the threshold, which corresponds to bias current values less than value I_{L} in the illustrated example. Thus, in the illustrated example, ensuring that a bias current of at least I_{L} is applied to the phase shift transistors 418-424 can reduce the intrinsic nonlinear behavior of the phase shift transistors 418-424 and. thereby, improve the INL performance of the phase shifter 400 of FIG. 4. In some examples, the value of I_{L} is 0.5 milliamperes (mA) or some other current value.

With the foregoing in mind, the FIG. 6 is a block diagram of a third example phase shifter circuit 600 that may be used to implement the phase shifters in the example system 100 of FIG. 1 and/or the example system 200 of FIG. 2. The third phase shifter circuit 600 is designed based on the nonlinear behavior curves 505-515 of FIGS. 5A-5C to help ensure the phase shift transistors 418-424 exhibit substantially linear operation, thereby improving INL performance of the phase shifter circuit 600 relative to the phase shifter circuit 400 and the phase shifter circuit 300.

Turning to FIG. 6, the phase shifter circuit 600 includes the modified Gilbert cell circuit architecture source signal transistors 402-416 (or local oscillator transistors 402-416) and the phase shift transistors 418-424 (or the DAC transistors 418-424) included in the phase shifter circuit 400 of FIG. 4. Also, in the phase shifter circuit 600 the source signal transistors 402-416 and the phase shift transistors 418-424 are arranged as in the phase shifter circuit 400 to implement the modified Gilbert cell circuit architecture that performs a complex multiplication of (i) the in-phase and quadrature source signals applied to the differential in-phase source inputs 255A-B and the differential quadrature source inputs 260A-B, respectively, with (ii) the in-phase and quadrature phase shift signals applied to the in-phase phase shift inputs 270A-B and the quadrature phase shift inputs 275A-B, respectively, to produce (iii) a phase-shifted output signal at the phase shifter outputs 265A-B. As described above in connection with FIG. 4, the phase-shifted output signal produced at the phase shifter outputs 265A-B corresponds to the input source signal but having a phase shift corresponding to the input phase shift signal.

Furthermore, relative to the phase shifter circuit 400 of FIG. 4, the phase shifter circuit 600 of FIG. 6 adds example bleed current sources 602, 604, 606 and 608 to help ensure the bias currents applied to the phase shift transistors 418-424 (or the DAC transistors 418-424) of the phase shifter circuit 600 cause the phase shift transistors 418-424 to exhibit substantially linear operation. More specifically, in the phase shifter circuit 600, the phase shift transistor 418 is included in an example circuit 610 that also includes the bleed current source 602, the phase shift transistor 420 is included in an example circuit 612 that also includes the bleed current source 604, the phase shift transistor 422 is included in an example circuit 614 that also includes the bleed current source 606, and the phase shift transistor 242 is included in an example circuit 614 that also includes the bleed current source 608. The bleed current sources 602-608 of the illustrated example can be implemented by any type of current source circuitry. For example, the bleed current sources 602-608 can be implemented by one or more current ladder circuits, one or more programmable amplifier circuits, etc.

In some examples, the bleed current sources 602-608 are programmable/controllable bleed current sources 602-608 that are controlled by one or more programmable circuit(s) and/or some other processor circuit(s), such as the DSP 152 of FIG. 1. For example, the DSP 152 (or other programmable/processor circuit) may program the bleed current sources 602-608 to output different bleed currents calibrated for different operating temperatures (e.g., as sensed by the temperature sensor 169), processes (e.g., specified based on configuration information), voltages (e.g., specified based on configuration information and/or as sensed by one or more voltage sensors), etc. In some examples, the DSP 152 (or other programmable/processor circuit) may be programmed with one or more data structures, such as one or more lookup tables, data arrays, linked lists, etc., that map different temperature, process and/or voltage operating values to corresponding bleed current values to be used to program the bleed current sources 602-608. As such, in some examples, the DSP 152 (or other programmable/processor circuit) may program the bleed current sources 602-608 to output a particular bleed current based on an initial temperature, process and/or voltage operating values of the phase shifter circuit 600, and then reprogram the bleed current sources 602-608 to output a different bleed current after detection of change in one or more of the temperature, process and/or voltage operating values of the phase shifter circuit 600.

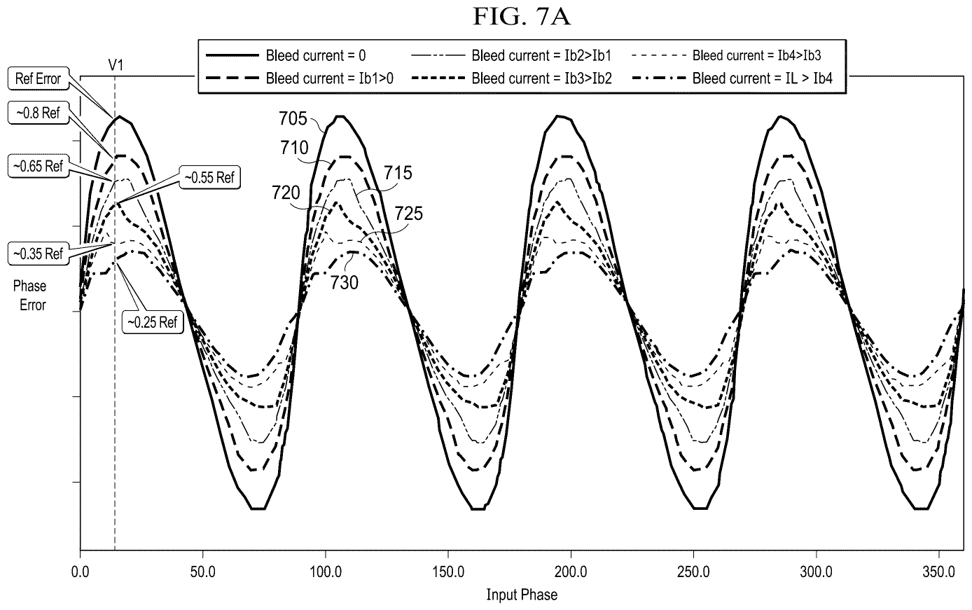

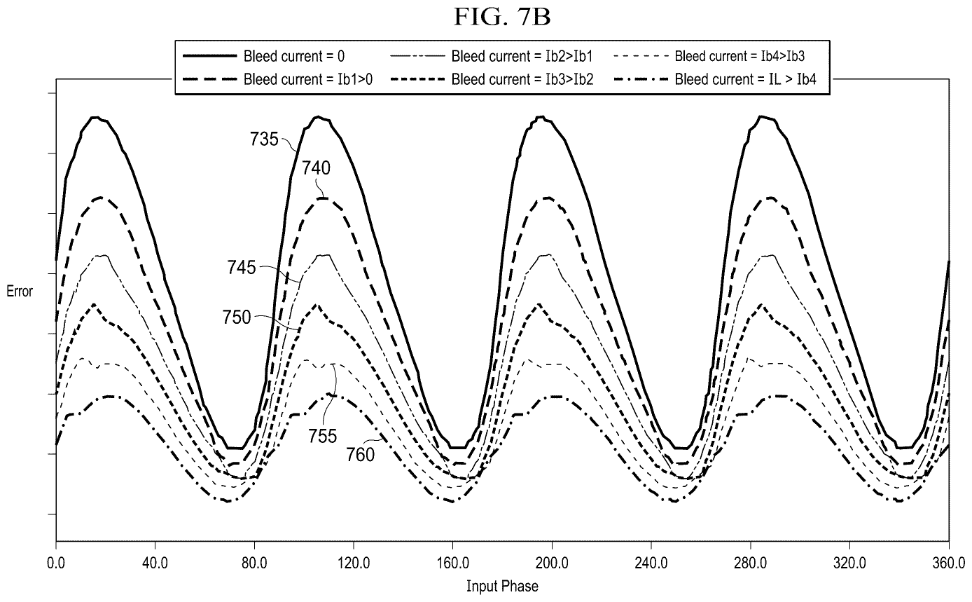

FIGS. 7A-7B illustrates example performance results associated with the phase shifter circuit 600 of FIG. 6. In particular, FIG. 7A illustrates example graphs 705, 710, 715, 720, 725 and 730 of phase error vs. input phase shift value for different values of the bleed current provided by the bleed current sources 602-608. FIG. 7B illustrates corresponding graphs 735, 740, 745, 750, 755 and 760 of denormalized phase error vs. input phase shift value for different values of the bleed current provided by the bleed current sources 602-608. In the illustrated examples of FIGS. 7A-7B, the graphs 705 and 735 correspond to a bleed current of 0 mA (e.g., no bleed current), the graphs 710 and 740 correspond to a bleed current of I_{b1}>0 mA, the graphs 715 and 745 correspond to a bleed current of I_{b2}>I_{b1} mA, the graphs 720 and 750 correspond to a bleed current of I_{b3}>I_{b2} mA, the graphs 725 and 755 correspond to a bleed current of I_{b4}>I_{b3} mA, and the graphs 730 and 760 correspond to a bleed current of I_{b5}=I_{L} mA.

The graphs of FIGS. 7A-7B illustrate that the phase error of the phase shifter circuit 600 decreases as the bleed current increases. Moreover, the graphs of FIGS. 7A-7B illustrate substantial phase error improvement relative to other phase shifter described above that have INL error in the range of 13-15 degrees. In contrast, as shown by the graphs of FIGS. 7A-7B, the phase shifter circuit 600 of FIG. 6 can achieve an INL improvement by a factor of 4 (or more) depending on the bias current provided by the bleed current sources 602-608. Furthermore, the graphs of FIGS. 7A-7B illustrate that the phase shifter circuit 600 can trade-off power consumption (e.g., bleed current) vs. phase error to tailor operation for a particular application.

With the foregoing in mind, in some examples, the DSP 152 (or other programmable/processor circuit) also includes one or more data structures, such as one or more lookup tables, data arrays, linked lists, etc., that map phase shift resolution to different bleed current values to allow the trade-off power consumption (e.g., bleed current) vs. phase error. For example, the DSP 152 can be programmed with a first data structure (e.g., lookup table) that maps phase shifts (e.g., from 0 to 360 degrees) to different in-phase and quadrature DAC input values at a first (e.g., lower) bit resolution for a first (e.g., lower) bleed current, and can be programmed with a second data structure (e.g., lookup table) that maps phase shifts (e.g., from 0 to 360 degrees) to different in-phase and quadrature DAC input values at a second (e.g., higher) bit resolution for a second (e.g., higher) bleed current.

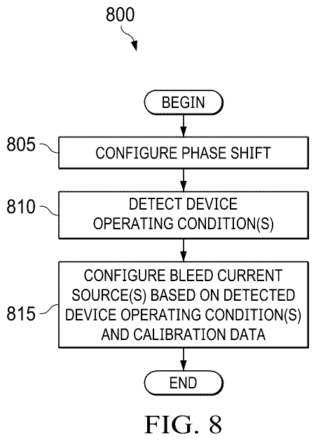

FIG. 8 is a flowchart representative of example machine-readable instructions and/or example operations 800 that may be at least one of executed, instantiated, or performed by programmable circuitry, such as the DSP 152 of FIG. 1 and/or any other programmable circuitry, such as the programmable circuitry 912 of the programmable circuitry platform 900, which is described in further detail below, to configure the example phase shifter circuit 600 of FIG. 6. For convenience and without loss of generality, the machine-readable instructions and/or example operations 800 of FIG. 8 are described from the perspective of being at least one of executed, instantiated, or performed by the DSP 152.

The example machine-readable instructions and/or the example operations 800 of FIG. 8 begin at block 805, at which the DSP 152 configures the DAC 225 with in-phase and quadrature components of a phase shift value to be applied by the phase shifter circuit 600. With reference to the description of FIGS. 7A-7B, the in-phase and quadrature components of a phase shift value may be binary values obtained by the DSP 152 from a data structure based on the currently configured bleed current value.

At block 810, the DSP 152 detects the current operating condition(s) of a device that includes (or otherwise implements) the phase shifter circuit 600. For example, at block 810, the DSP 152 may detect the operating temperature of the device using the temperature sensor 169. Additionally or alternatively, the DSP 152 may detect the operating voltage of the device using a voltage sensor.

At block 815, the DSP 152 configures the bleed current sources 602-608 of the phase shifter circuit 600 based on the device operating conditions detected at block 815 and calibration data. For example, the calibration data may calibrate the value of the bleed current to be output from the bleed current sources 602-608 for different operating temperatures (e.g., as sensed by the temperature sensor 169 at block 810), processes used to implement the phase shifter circuit 600 (e.g., as specified based on configuration information), voltages (e.g., specified based on configuration information and/or as detected based on one or more voltage sensors at block 810), etc. The machine-readable instructions and/or example operations 800 then end.

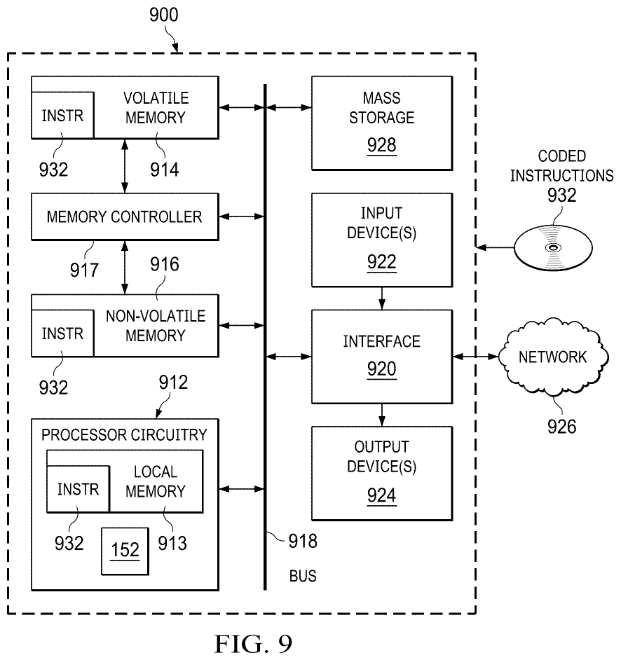

FIG. 9 is a block diagram of an example programmable circuitry platform 900 structured to one or a combination of execute or instantiate one or more of the example machine-readable instructions or the example operations of FIG. 8 to configure the example phase shifter circuit 600 of FIG. 6. The programmable circuitry platform 900 can be, for example, a radar system, a communications system, a mobile device (e.g., a cell phone, a smart phone, a tablet such as an iPad™), or any other type of computing or electronic device.

The programmable circuitry platform 900 of the illustrated example includes programmable circuitry 912. The programmable circuitry 912 of the illustrated example is hardware. For example, the programmable circuitry 912 can be implemented by one or more integrated circuits, logic circuits, FPGAs, microprocessors, CPUs, GPUs, DSPs, or microcontrollers from any desired family or manufacturer. The programmable circuitry 912 may be implemented by one or more semiconductor based (e.g., silicon based) devices. In this example, the programmable circuitry 912 implements the DSP 152.

The programmable circuitry 912 of the illustrated example includes a local memory 913 (e.g., a cache, registers, etc.). The programmable circuitry 912 of the illustrated example is in communication with main memory 914, 916, which includes a volatile memory 914 and a non-volatile memory 916, by a bus 918. The volatile memory 914 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 916 may be implemented by one or a combination of flash memory or any other desired type of memory device. Access to the main memory 914, 916 of the illustrated example is controlled by a memory controller 917. In some examples, the memory controller 917 may be implemented by one or more integrated circuits, logic circuits, microcontrollers from any desired family or manufacturer, or any other type of circuitry to manage the flow of data going to and from the main memory 914, 916.

The programmable circuitry platform 900 of the illustrated example also includes interface circuitry 920. The interface circuitry 920 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 922 are connected to the interface circuitry 920. The input device(s) 922 permit(s) a user (e.g., a human user, a machine user, etc.) to enter one of or a combination of data or commands into the programmable circuitry 912. The input device(s) 922 can be implemented by, for example, one of or a combination of an audio sensor, a microphone, a camera (still or video), a keyboard, a button, a voice recognition system, etc.

One or more output devices 924 are also connected to the interface circuitry 920 of the illustrated example. The output device(s) 924 can be implemented, for example, by one of or a combination of the PA 230 and the antenna 235.

Thus, the interface circuitry 920 of the illustrated example may include a communication device such as one of or a combination of a transmitter, a receiver, a transceiver, a modem, a residential gateway, a wireless access point, or a network interface to facilitate exchange of data with external machines (e.g., computing devices of any kind) by a network 926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc. The interface circuitry 920 of the illustrated example may also include one of or a combination of a graphics driver card, a graphics driver chip, or graphics processor circuitry such as a GPU.

The programmable circuitry platform 900 of the illustrated example also includes one or more mass storage discs or devices 928 to store one or more of firmware, software, or data. Examples of such mass storage discs or devices 928 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 932, which may be implemented by the machine-readable instructions of FIG. 8, may be stored in one of or a combination of the mass storage device 928, in the volatile memory 914, in the non-volatile memory 916, or on at least one non-transitory computer-readable storage medium such as a CD or DVD which may be removable.

While an example manner of implementing the phase shifter circuit 600 is illustrated in FIG. 6, one or more of the elements, processes, or devices illustrated in FIG. 6 may be combined, divided, re-arranged, omitted, eliminated, or implemented in any other way. Further still, the example phase shifter circuit 600 of FIG. 6 may include one or more elements, processes, or devices in addition to, or instead of, those illustrated in FIG. 6, or may include more than one of any or all of the illustrated elements, processes and devices.

Flowchart(s) representative of example machine-readable instructions, which may be executed by programmable circuitry to configure the phase shifter circuit 600 of FIG. 6 or representative of example operations which may be performed by programmable circuitry to at least one of configure the phase shifter circuit 600 of FIG. 6, are shown in FIG. 8. The machine-readable instructions may be one or more executable programs or portion(s) of one or more executable programs for execution by programmable circuitry such as the programmable circuitry 912 shown in the example processor platform 900 discussed below in connection with FIG. 9 and may be one or more function(s) or portion(s) of functions to be performed by the example programmable circuitry (e.g., an FPGA). In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer-readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer-readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer-readable storage medium may include one or more mediums. Further, although the example program is described with reference to the flowchart(s) illustrated in FIG. 8, many other methods of configuring the example phase shifter circuit 600 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, one of or a combination of a CPU or an FPGA. The programmable circuitry may include one or more CPUs and/or one or more FPGAs located in the same package (e.g., the same integrated circuit (IC) package or in two or more separate housings), one or more CPUs or FPGAs in a single machine, one or multiple CPUs or FPGAs distributed across multiple servers of a server rack, multiple processors distributed across one or more server racks. Also or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., or any combination(s) thereof in any of the contexts explained above.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer-readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIG. 8 may be implemented using executable instructions (e.g., computer-readable and/or machine-readable instructions) stored on one or more non-transitory computer-readable or machine-readable media. As used herein, the terms non-transitory computer-readable medium, non-transitory computer-readable storage medium, non-transitory machine-readable medium, and non-transitory machine-readable storage medium are expressly defined to include any type of computer-readable storage device or storage disk and to exclude propagating signals and to exclude transmission media. Examples of such non-transitory computer-readable medium, non-transitory computer-readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer-readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer-readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer-readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described to implement phase shifter circuit architectures. Described systems, apparatus, articles of manufacture, and methods improve the efficiency of phase shifter circuits by repositioning the transistors used to receive the input signals that correspond to the configured (e.g., programmed) phase shift to allow such signals to have a higher dynamic range than is possible with the other phase shifters, which can improve the linearity of the configured phase shifts represented by those input signals. Such transistor repositioning also reduces or eliminates other causes of circuit nonlinearity, such as parasitic capacitance, without any significant increases in chip area and power dissipation. Some example phase shifter architectures described herein also include programmable bleed current sources to bias the input signals corresponding to the configured (e.g., programmed) phase shift to have signal values outside a range in which the phase shifter circuit may exhibit substantial INL, thereby further improving INL performance relative to other phase shifters. Described systems, apparatus, articles of manufacture, and methods are also directed to one or more improvement(s) in the operation of a phase shifter circuit or other electronic mechanical device.

Further examples and combinations thereof include the following. Example 1 includes a device comprising a first circuit configurable to be coupled to a digital-to-analog converter (DAC), a second circuit configurable to be coupled to the DAC, a first transistor including a first load terminal, a second load terminal coupled to a ground node, and a first control terminal coupled to the first circuit, a second transistor including a third load terminal, a fourth load terminal coupled to the ground node, and a second control terminal coupled to the first circuit, a third transistor including a fifth load terminal coupled to the third load terminal of the second transistor, a sixth load terminal coupled to the ground node, and a third control terminal coupled to the second circuit, and a fourth transistor including a seventh load terminal coupled to the first load terminal of the first transistor, an eighth load terminal coupled to the ground node, and a fourth control terminal coupled to the second circuit.

Example 2 includes the device of example 1, further comprising a power amplifier including a first input coupled to the first load terminal and the seventh load terminal, and a second input coupled to the third load terminal and the fifth load terminal.

Example 3 includes the device of example 1, wherein the first load terminal and the seventh load terminal are coupled to a first circuit output, and wherein the third load terminal and the fifth load terminal are coupled to a second circuit output.

Example 4 includes the device of any one of examples 1 to 3, further comprising the DAC coupled to the first circuit and the second circuit.

Example 5 includes the device of any one of examples 1 to 4, further comprising a first programmable current source coupled to the first circuit, and a second programmable current source coupled to the second circuit.

Example 6 includes the device of example 5, wherein the DAC includes a first DAC output and a second DAC output, and wherein the first circuit is configurable to couple the first DAC output to the first programmable current source, and the second circuit is configurable to couple the second DAC output to the second programmable current source.

Example 7 includes a device comprising a first circuit configurable to be coupled to a first digital-to-analog converter (DAC) output, the first DAC output configurable to provide a first current corresponding to an in-phase component of a phase shift, a second circuit configurable to be coupled to a second DAC output, the second DAC output configurable to provide a second current corresponding to a quadrature component of the phase shift, a first transistor having a first load terminal, a second load terminal and a control terminal, the control terminal of the first transistor coupled to the first circuit, a second transistor having a first load terminal, a second load terminal and a control terminal, the control terminal of the second transistor coupled to the first circuit, a third transistor having a first load terminal, a second load terminal and a control terminal, the control terminal of the third transistor coupled to the second circuit, and a fourth transistor having a first load terminal, a second load terminal and a control terminal, the control terminal of the fourth transistor coupled to the second circuit, wherein the first load terminals of the first transistor, the second transistor, the third transistor and the fourth transistor are cross-coupled to a circuit output, the circuit output to provide an output signal based on the phase shift.

Example 8 includes the device of example 7, wherein the second load terminals of the first transistor, the second transistor, the third transistor and the fourth transistor are coupled to a ground node.

Example 9 includes the device of example 8, wherein the first transistor, the second transistor, the third transistor and the fourth transistor are bipolar junction transistors, and the first load terminals are respective collector terminals of the first transistor, the second transistor, the third transistor and the fourth transistor, the second load terminals are respective emitter terminals of the first transistor, the second transistor, the third transistor and the fourth transistor, and the control terminals are respective bias terminals of the first transistor, the second transistor, the third transistor and the fourth transistor.

Example 10 includes the device of example 8, wherein the first transistor, the second transistor, the third transistor and the fourth transistor are field effect transistors, and the first load terminals are respective drain terminals of the first transistor, the second transistor, the third transistor and the fourth transistor, the second load terminals are respective source terminals of the first transistor, the second transistor, the third transistor and the fourth transistor, and the control terminals are respective gate terminals of the first transistor, the second transistor, the third transistor and the fourth transistor.

Example 11 includes the device of any one of examples 7 to 10, including a first programmable current source coupled to the first circuit, and a second programmable current source coupled to the second circuit.

Example 12 includes the device of example 11, wherein the first circuit is configurable to couple the first DAC output to the first programmable current source, and the second circuit is configurable to couple the second DAC output to the second programmable current source.

Example 13 includes the device of any one of examples 7 to 12, wherein the first DAC output includes a non-inverted first DAC output and an inverted first DAC output, the second DAC output includes a non-inverted second DAC output and an inverted second DAC output, and the first circuit includes a fifth transistor and a sixth transistor, the fifth transistor configurable to be coupled to the non-inverted first DAC output, the sixth transistor configurable to be coupled to the inverted first DAC output, and the second circuit includes a seventh transistor and an eighth transistor, the seventh transistor configurable to be coupled to the non-inverted second DAC output, the eighth transistor configurable to be coupled to the inverted second DAC output.

Example 14 includes the device of example 13, wherein the control terminal of the first transistor is coupled to the fifth transistor, the control terminal of the second transistor is coupled to the fifth transistor, the control terminal of the third transistor is coupled to the seventh transistor, the control terminal of the second transistor is coupled to the seventh transistor, and the device includes a ninth transistor having a first load terminal, a second load terminal and a control terminal, the control terminal of the ninth transistor coupled to the sixth transistor, a tenth transistor having a first load terminal, a second load terminal and a control terminal, the control terminal of the tenth transistor coupled to the sixth transistor, an eleventh transistor having a first load terminal, a second load terminal and a control terminal, the control terminal of the eleventh transistor coupled to the eighth transistor, and a twelfth transistor having a first load terminal, a second load terminal and a control terminal, the control terminal of the twelfth transistor coupled to the eighth transistor.

Example 15 includes the device of example 14, wherein the circuit output includes a non-inverted circuit output and an inverted circuit output, and the first load terminals of the first transistor, the fourth transistor, the tenth transistor, and the eleventh transistor are coupled to the non-inverted circuit output, and the first load terminals of the second transistor, the third transistor, the ninth transistor, and the twelfth transistor are coupled to the inverted circuit output.

Example 16 includes the device of example 13, including a first programmable current source coupled to the fifth transistor, a second programmable current source coupled to the sixth transistor, a third programmable current source coupled to the seventh transistor, and a fourth programmable current source coupled to the eighth transistor.

Example 17 includes the device of example 16, wherein the fifth transistor is configurable to couple the non-inverted first DAC output to the first programmable current source, the sixth transistor is configurable to couple the inverted first DAC output to the second programmable current source, the seventh transistor is configurable to couple the non-inverted second DAC output to the third programmable current source, and the eighth transistor is configurable to couple the inverted second DAC output to the fourth programmable current source.

Example 18 includes a device comprising an antenna, a power amplifier coupled to the antenna, a digital-to-analog converter (DAC) circuit having a first DAC output and a second DAC output, first circuitry coupled to the first DAC output, second circuitry coupled to the second DAC output, and a first transistor having a first load terminal, a second load terminal and a control terminal, the control terminal of the first transistor coupled to the first circuitry, the second load terminal of the first transistor coupled to a ground node, a second transistor having a first load terminal, a second load terminal and a control terminal, the control terminal of the second transistor coupled to the first circuitry, the second load terminal of the second transistor coupled to the ground node, a third transistor having a first load terminal, a second load terminal and a control terminal, the control terminal of the third transistor coupled to the second circuitry, the second load terminal of the third transistor coupled to the ground node, and a fourth transistor having a first load terminal, a second load terminal and a control terminal, the control terminal of the fourth transistor coupled to the second circuitry, the second load terminal of the fourth transistor coupled to the ground node, wherein the first load terminals of the first transistor and the third transistor are coupled to a first circuit output, the first load terminals of the second transistor and the fourth transistor are coupled to a second circuit output, and the first circuit output and the second circuit output are coupled to the power amplifier.

Example 19 includes the device of example 18, wherein the first circuitry is coupled to a first programmable bleed current source, and the second circuitry is coupled to a second programmable bleed current source.

Example 20 includes the device of example 19, wherein the DAC circuit is configurable to provide a first current at the first DAC output and a second current at the second DAC output, the first current corresponding to an in-phase component of a phase shift, the second current corresponding to a quadrature component of the phase shift, and the device includes a processor circuit configured to configure the phase shift, configure the first programmable bleed current source, and configure the second programmable bleed current source.

The following claims are hereby incorporated into this Detailed Description by this reference. Although certain example systems, apparatus, articles of manufacture, and methods have been described herein, the scope of coverage of this patent is not limited thereto. On the contrary, this patent covers all systems, apparatus, articles of manufacture, and methods fairly falling within the scope of the claims of this patent.

What is claimed is:

1. A device comprising:
a first circuit configurable to be coupled to a digital-to-analog converter (DAC);
a second circuit configurable to be coupled to the DAC;
a first transistor including:
a first load terminal;
a second load terminal coupled to a ground node; and
a first control terminal coupled to the first circuit;
a second transistor including:
a third load terminal;
a fourth load terminal coupled to the ground node; and
a second control terminal coupled to the first circuit;
a third transistor including:
a fifth load terminal coupled to the third load terminal of the second transistor;
a sixth load terminal coupled to the ground node; and
a third control terminal coupled to the second circuit; and
a fourth transistor including:
a seventh load terminal coupled to the first load terminal of the first transistor;
an eighth load terminal coupled to the ground node; and
a fourth control terminal coupled to the second circuit.

2. The device of claim 1, further comprising a power amplifier including:
a first input coupled to the first load terminal and the seventh load terminal; and
a second input coupled to the third load terminal and the fifth load terminal.

3. The device of claim 1,
wherein the first load terminal and the seventh load terminal are coupled to a first circuit output, and
wherein the third load terminal and the fifth load terminal are coupled to a second circuit output.

4. The device of claim 1, further comprising the DAC coupled to the first circuit and the second circuit.

5. The device of claim 1, further comprising:
a first programmable current source coupled to the first circuit; and
a second programmable current source coupled to the second circuit.

6. The device of claim 5, wherein the DAC includes a first DAC output and a second DAC output, and wherein:
the first circuit is configurable to couple the first DAC output to the first programmable current source; and
the second circuit is configurable to couple the second DAC output to the second programmable current source.

7. A device comprising:
a first circuit configurable to be coupled to a first digital-to-analog converter (DAC) output, the first DAC output configurable to provide a first current corresponding to an in-phase component of a phase shift;
a second circuit configurable to be coupled to a second DAC output, the second DAC output configurable to provide a second current corresponding to a quadrature component of the phase shift;
a first transistor having a first load terminal, a second load terminal and a control terminal, the control terminal of the first transistor coupled to the first circuit;
a second transistor having a first load terminal, a second load terminal and a control terminal, the control terminal of the second transistor coupled to the first circuit;
a third transistor having a first load terminal, a second load terminal and a control terminal, the control terminal of the third transistor coupled to the second circuit; and
a fourth transistor having a first load terminal, a second load terminal and a control terminal, the control terminal of the fourth transistor coupled to the second circuit,
wherein the first load terminals of the first transistor, the second transistor, the third transistor and the fourth transistor are cross-coupled to a circuit output, the circuit output to provide an output signal based on the phase shift.

8. The device of claim 7, wherein the second load terminals of the first transistor, the second transistor, the third transistor and the fourth transistor are coupled to a ground node.

9. The device of claim 8, wherein the first transistor, the second transistor, the third transistor and the fourth transistor are bipolar junction transistors, and:
the first load terminals are respective collector terminals of the first transistor, the second transistor, the third transistor and the fourth transistor,
the second load terminals are respective emitter terminals of the first transistor, the second transistor, the third transistor and the fourth transistor, and
the control terminals are respective bias terminals of the first transistor, the second transistor, the third transistor and the fourth transistor.

10. The device of claim 8, wherein the first transistor, the second transistor, the third transistor and the fourth transistor are field effect transistors, and:
the first load terminals are respective drain terminals of the first transistor, the second transistor, the third transistor and the fourth transistor,
the second load terminals are respective source terminals of the first transistor, the second transistor, the third transistor and the fourth transistor, and
the control terminals are respective gate terminals of the first transistor, the second transistor, the third transistor and the fourth transistor.

11. The device of claim 7, including:
a first programmable current source coupled to the first circuit; and
a second programmable current source coupled to the second circuit.

12. The device of claim 11, wherein:
the first circuit is configurable to couple the first DAC output to the first programmable current source; and
the second circuit is configurable to couple the second DAC output to the second programmable current source.

13. The device of claim 7, wherein the first DAC output includes a non-inverted first DAC output and an inverted first DAC output, the second DAC output includes a non-inverted second DAC output and an inverted second DAC output, and:
the first circuit includes a fifth transistor and a sixth transistor, the fifth transistor configurable to be coupled to the non-inverted first DAC output, the sixth transistor configurable to be coupled to the inverted first DAC output, and
the second circuit includes a seventh transistor and an eighth transistor, the seventh transistor configurable to be coupled to the non-inverted second DAC output, the eighth transistor configurable to be coupled to the inverted second DAC output.

14. The device of claim 13, wherein:
the control terminal of the first transistor is coupled to the fifth transistor;
the control terminal of the second transistor is coupled to the fifth transistor;
the control terminal of the third transistor is coupled to the seventh transistor;
the control terminal of the second transistor is coupled to the seventh transistor; and
the device includes:
a ninth transistor having a first load terminal, a second load terminal and a control terminal, the control terminal of the ninth transistor coupled to the sixth transistor;
a tenth transistor having a first load terminal, a second load terminal and a control terminal, the control terminal of the tenth transistor coupled to the sixth transistor;
an eleventh transistor having a first load terminal, a second load terminal and a control terminal, the control terminal of the eleventh transistor coupled to the eighth transistor; and
a twelfth transistor having a first load terminal, a second load terminal and a control terminal, the control terminal of the twelfth transistor coupled to the eighth transistor.

15. The device of claim 14, wherein the circuit output includes a non-inverted circuit output and an inverted circuit output, and:
the first load terminals of the first transistor, the fourth transistor, the tenth transistor, and the eleventh transistor are coupled to the non-inverted circuit output, and
the first load terminals of the second transistor, the third transistor, the ninth transistor, and the twelfth transistor are coupled to the inverted circuit output.

16. The device of claim 13, including:
a first programmable current source coupled to the fifth transistor;
a second programmable current source coupled to the sixth transistor;
a third programmable current source coupled to the seventh transistor; and
a fourth programmable current source coupled to the eighth transistor.

17. The device of claim 16, wherein
the fifth transistor is configurable to couple the non-inverted first DAC output to the first programmable current source;
the sixth transistor is configurable to couple the inverted first DAC output to the second programmable current source;
the seventh transistor is configurable to couple the non-inverted second DAC output to the third programmable current source; and
the eighth transistor is configurable to couple the inverted second DAC output to the fourth programmable current source.

18. A device comprising:
an antenna;
a power amplifier coupled to the antenna;
a digital-to-analog converter (DAC) circuit having a first DAC output and a second DAC output;
first circuitry coupled to the first DAC output;
second circuitry coupled to the second DAC output; and
a first transistor having a first load terminal, a second load terminal and a control terminal, the control terminal of the first transistor coupled to the first circuitry, the second load terminal of the first transistor coupled to a ground node;
a second transistor having a first load terminal, a second load terminal and a control terminal, the control terminal of the second transistor coupled to the first circuitry, the second load terminal of the second transistor coupled to the ground node;
a third transistor having a first load terminal, a second load terminal and a control terminal, the control terminal of the third transistor coupled to the second circuitry, the second load terminal of the third transistor coupled to the ground node; and
a fourth transistor having a first load terminal, a second load terminal and a control terminal, the control terminal of the fourth transistor coupled to the second circuitry, the second load terminal of the fourth transistor coupled to the ground node,
wherein the first load terminals of the first transistor and the third transistor are coupled to a first circuit output, the first load terminals of the second transistor and the fourth transistor are coupled to a second circuit output, and the first circuit output and the second circuit output are coupled to the power amplifier.

19. The device of claim 18, wherein:
the first circuitry is coupled to a first programmable bleed current source; and
the second circuitry is coupled to a second programmable bleed current source.

20. The device of claim 19, wherein the DAC circuit is configurable to provide a first current at the first DAC output and a second current at the second DAC output, the first current corresponding to an in-phase component of a phase shift, the second current corresponding to a quadrature component of the phase shift, and the device includes a processor circuit configured to:
configure the phase shift;
configure the first programmable bleed current source; and
configure the second programmable bleed current source.
